(19) United States
(12) Patent Application Publication
(10) Pub. No.: US 2008/0079106 A1
(43) Pub. Date: Apr. 3, 2008

(54) SOLID-STATE IMAGING DEVICE

(75) Inventors: Ryohei MIYAGAWA, Kyoto (JP); Shuichi MAYUMI, Kyoto (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/865,271

(22) Filed: Oct. 1, 2007

(30) Foreign Application Priority Data
Oct. 2, 2006 (JP) 2006-271237

(51) Int. Cl. H01L 31/0216

(52) U.S. Cl. 257/437; 257/E31.123

(57) ABSTRACT

A solid-state imaging device according to the present invention includes a semiconductor substrate; a light-receiving element formed in the semiconductor substrate and photoelectrically converting incident light; and a plurality of wiring layers stacked on top of each other on a surface of the semiconductor substrate where the light-receiving element is formed. At least one of the plurality of wiring layers includes: a first insulating layer; metal wiring formed on the first insulating layer; an antireflection layer stacked on the first insulating layer and the metal wiring, preventing diffusion of a material making up of the metal wiring, and preventing reflection of the incident light; and a second insulating layer stacked on the antireflection layer.

### BACKGROUND OF THE INVENTION

(1) Field of the Invention

The present invention relates to a solid-state imaging device, and more particularly to a solid-state imaging device using metal wirings having a multilayer structure and made of copper or the like.

(2) Description of the Related Art

Solid-state imaging devices such as CMOS image sensors are used as image sensors for use in digital cameras, mobile phone cameras, web cameras, etc. In recent years, there have been an increase in the number of pixels and a reduction in the size of pixels of solid-state imaging devices. Accordingly, metal wirings to be used are changed to Cu (copper) wirings from Al (aluminum) wirings.

When Cu wirings are used, since the diffusion coefficient of Cu in an oxide film is large, there is a need to form a layer that prevents Cu diffusion.

FIG. 1 is a diagram showing a cross-sectional structure of a conventional solid-state imaging device using Cu wirings. A conventional solid-state imaging device 500 shown in FIG. 1 is a CMOS image sensor and includes a semiconductor substrate 501, a photodiode 502, a transistor 503, interlayer films 504, 507, and 510, Cu wirings 505, 508, and 511, diffusion preventing layers 506, 509, 512, and 513, a protective film 514, a color filter 515, a microlens 516, and element isolation regions 517.

The photodiode 502 performs photoelectric conversion of incident light. The transistor 503 includes a gate electrode 518 formed of polysilicon. The element isolation regions 517 are an element isolation layer (STI: Shallow Trench Isolation) made of an SiO₂ buried layer. The interlayer films 504, 507, and 510 and the protective film 514 are made of SiO₂, for example. The Cu wirings 505, 508, and 511 are metal wirings made of Cu. The diffusion preventing layers 506, 509, 512, and 513 are layers for preventing diffusion of Cu making up of the Cu wirings 505, 508, and 511, and are made of SiN, for example.

In the solid-state imaging device 500, following layers are formed on the semiconductor substrate 501 in the following order, the photodiode 502, the transistor 503, the interlayer film 504, the Cu wirings 505, the diffusion preventing layer 506, the interlayer film 507, the Cu wirings 508, the diffusion preventing layer 509, the interlayer film 510, the Cu wirings 511, the diffusion preventing layer 512, the diffusion preventing layer 513, the protective film 514, the color filter 515, and the microlens 516.

Light incident on the solid-state imaging device 500 is collected by the microlens 516 and the collected light is irradiated onto the photodiode 502. However, in the conventional solid-state imaging device shown in FIG. 1, layers made of SiO₂ (the interlayer films 504, 507, and 510 and the protective film 514) and layers made of SiN (the diffusion preventing layers 506, 509, 512, and 513), which have different refractive indices, are stacked on top of one another above the photodiode 502. Because of this, reflection (e.g., an arrow 521 shown in FIG. 1) and multiple interference (e.g., arrows 519 and 520 shown in FIG. 1) occur at interfaces between the interlayer films and the diffusion preventing layers. Due to the influence of the reflection and multiple interference, there are problems of reduction in the amount of light incident on the photodiode 502 and increase in the occurrence of noise. In view of this, a method is known for removing portions of the diffusion preventing layers above the photodiode 502.

For the method of removing portions of the diffusion preventing layers above the photodiode 502, there are known a first method (see Japanese Unexamined Patent Application Publication No. 2005-311015, for example) in which layers are formed while portions of diffusion preventing layers are sequentially removed and a second method (see Japanese Unexamined Patent Application Publications No. 2005-311015, No. 2004-221527, and No. 2006-80522, for example) in which after all layers are formed, portions of diffusion preventing layers above the photodiode 502 are removed at a time and then an insulating layer is buried.

FIG. 2 is a diagram showing a cross-sectional structure of a conventional solid-state imaging device formed by the first method in which layers are formed while portions of diffusion preventing layers are sequentially removed. A conventional solid-state imaging device 600 shown in FIG. 2 includes diffusion preventing layers 606, 609, 612, and 613, portions of which above the photodiode 502 are removed. Note that the same components as those in FIG. 1 are denoted by the same reference numerals.

A fabricating method of the solid-state imaging device 600 is as follows. On a semiconductor substrate 501, an interlayer film 504, Cu wirings 505, and a diffusion preventing layer 606 are sequentially stacked. Then, a portion of the diffusion preventing layer 606 above the photodiode 502 is removed. Furthermore, an interlayer film 507, Cu wirings 508, and a diffusion preventing layer 609 are sequentially stacked. Then, a portion of the diffusion preventing layer 609 above the photodiode 502 is removed. Furthermore, an interlayer film 510, Cu wirings 511, and diffusion preventing layers 612 and 613 are sequentially stacked. Then, portions of the diffusion preventing layers 612 and 613 above the photodiode 502 are removed.

Accordingly, in the conventional solid-state imaging device 600, there is no diffusion preventing layer above the photodiode 502 and there are only interlayer films having the same refractive index formed above the photodiode 502. With this, the occurrence of reflection and multiple interference is reduced, making it possible to prevent a reduction in the amount of light incident on the photodiode 502.

FIG. 3 is a diagram showing a cross-sectional structure of a conventional solid-state imaging device formed by the second method in which after all layers are formed, portions of diffusion preventing layers above a photodiode are removed at a time and then an insulating layer is buried. A conventional solid-state imaging device 700 shown in FIG. 3 is different from the solid-state imaging device 500 shown in FIG. 1 in that the solid-state imaging device 700 includes diffusion preventing layers 706, 709, 712, and 713, with portions above a photodiode 502 are removed, and an buried insulating layer 722 formed in a region where the portions of the diffusion preventing layers above the photodiode 502 are removed. Note that the same components as those in FIG. 1 are denoted by the same reference numerals.

A fabricating method of the solid-state imaging device 700 is as follows. On a semiconductor substrate 501, an interlayer film 504, Cu wirings 505, a diffusion preventing layer 706, an interlayer film 507, Cu wirings 508, a diffusion preventing layer 709, an interlayer film 510, Cu wirings 511, diffusion preventing layers 712 and 713, and a protective film 514 are sequentially stacked. Then, portions of the diffusion preventing layers 706, 709, 712, and 713, the interlayer films 504, 507, and 510, and the protective film 514 above a photodiode 502 are removed at a time. Then, an buried insulating layer 722 is buried in a region where the portions of the diffusion preventing layers 706, 709, 712, and 713, the interlayer films 504, 507, and 510, and the protective film 514 above the photodiode 502 are removed at a time.

Accordingly, in the conventional solid-state imaging device 700, there is no diffusion preventing layer formed above the photodiode 502 and there are only the interlayer film 504 and the buried insulating layer 722 which have the same refractive index formed above the photodiode 502. With this, the occurrence of reflection and multiple interference is reduced, making it possible to prevent a reduction in the amount of light incident on the photodiode 502.

### SUMMARY OF THE INVENTION

However, in the first method, such as the method shown in FIG. 2, in which layers are formed while portions of diffusion preventing layers are sequentially removed, process steps of removing portions of diffusion preventing layers are required, causing a problem that the number of process steps increases. Furthermore, by removing portions of the diffusion preventing layers, the flatness of interlayer films to be stacked on the diffusion preventing layers is reduced. Although the reduction in flatness can be solved by planarization, the number of process steps further increases by performing planarization.

In the second method, such as the method shown in FIG. 3, in which after all layers are formed, portions of diffusion preventing layers above a photodiode are removed at a time and then an insulating layer is buried, the aspect ratio for burying is high and thus there is a problem that high processing techniques are required to form an buried insulating layer 722 with few defects. Since the buried insulating layer 722 is formed above the photodiode 502, when the buried insulating layer 722 is incomplete and a defect such as a void occurs, incident light reflects off such a defective portion, significantly influencing on the characteristics of the solid-state imaging device. Hence, the buried insulating layer 722 needs to be a high-quality layer with no defects. In addition, when a solid-state imaging device becomes finer, the aspect ratio for burying further increases and accordingly the degree of difficulty of process associated with forming a buried insulating layer further increases.

In view of this, it is an object of the present invention to provide a solid-state imaging device that is capable of preventing a reduction in the amount of light incident on a photodiode, has a low degree of difficulty of process, and suppresses an increase in the number of process steps.

In order to achieve the above object, a solid-state imaging device according to the present invention includes: a semiconductor substrate; a light-receiving element formed on the semiconductor substrate and which photoelectrically converts incident light; and a plurality of wiring layers stacked on top of each other on a surface of the semiconductor substrate where the light-receiving element is formed, in which at least one of the plurality of wiring layers includes: a first insulating layer; a metal wiring formed on the first insulating layer; an antireflection layer stacked on the first insulating layer and the metal wiring, and which prevents diffusion of a material making up of the metal wiring and prevents reflection of the incident light; and a second insulating layer stacked on the antireflection layer.

With this configuration, since the antireflection layer has the function of preventing reflection of incident light, reflection and multiple interference occurring at an interface between the antireflection layer and the second insulating layer can be reduced. With this, the reduction in the amount of light incident on a photodiode can be prevented. In addition, since the solid-state imaging device according to the present invention can be implemented by forming the antireflection layer having the function of preventing reflection, without performing a process step of removing a portion of the antireflection layer, or the like, the degree of difficulty of process is low and the increase in the number of process steps can be suppressed.

In addition, the antireflection layer may have a refractive index or layer thickness which corresponds to a peak transmittance in transmittance characteristics of the incident light with respect to the refractive index or layer thickness of the antireflection layer.

With this configuration, since optimization is done such that the antireflection layer achieves a high transmittance of incident light, reflection and multiple interference occurring at an interface between the antireflection layer and a second insulating layer can be reduced.

In addition, the antireflection layer may include: a first antireflection layer stacked on the first insulating layer and the metal wiring; and a second antireflection layer stacked on the first antireflection layer and made of a material having a refractive index different from a refractive index of a material making up of the first antireflection layer.

With this configuration, the antireflection layer is made of two layers. With this, for example, the first antireflection layer adjacent to metal wirings has the function of preventing diffusion of the metal wirings and by changing the refractive index and thickness of the second antireflection layer, the transmittance of the antireflection layer for incident light can be easily optimized.

In addition, the first antireflection layer may be made of a material that does not contain oxygen.

With this configuration, the first antireflection layer adjacent to metal wirings has the function of preventing diffusion of the metal wirings. With this, for example, by changing the refractive index and thickness of the second antireflection layer, the transmittance of the antireflection layer for incident light can be easily optimized.

In addition, the material that does not contain oxygen may be SiN, SiC, or SiNC.

With this configuration, the first antireflection layer can be easily formed in an existing fabrication process.

In addition, the second antireflection layer may be made of a material that contains oxygen.

With this configuration, by changing the oxygen content in a second antireflection layer, the refractive index of the second antireflection layer can be easily changed. With this, the transmittance of an antireflection layer for incident light can be easily optimized.

In addition, the material that contains oxygen may be SiON, SiONC, or SiO₂.

With this configuration, the second antireflection layer can be easily formed in an existing fabrication process.

In addition, the antireflection layer may further include a third antireflection layer stacked on the second antireflection layer and made of a material having a refractive index different from that of the material making up of the second antireflection layer.

With this configuration, by changing the oxygen content in the third antireflection layer, the antireflection layer can obtain an antireflection effect on incident light by a multiple reflection effect.

In addition, the solid-state imaging device may further include an antireflection film which is formed on the light-receiving element and below the plurality of wiring layers and prevents reflection of the incident light.

With this configuration, reflection occurring at an interface between a photodiode and the first insulating layer can be reduced. With this, the reduction in the amount of light incident on the photodiode can be more effectively reduced.

In addition, the metal wiring may be made of copper.

With this configuration, in a solid-state imaging device using copper wirings, the reduction in the amount of light incident on a photodiode can be prevented. In addition, the degree of difficulty of process is reduced and the increase in the number of process steps can be suppressed.

The present invention can provide a solid-state imaging device that is capable of preventing a reduction in the amount of light incident on a photodiode, has a low degree of difficulty of process, and suppresses an increase in the number of process steps.

### FURTHER INFORMATION ABOUT TECHNICAL BACKGROUND TO THIS APPLICATION

The disclosure of Japanese Patent Application No. 2006-271237 filed on Oct. 2, 2006 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing a cross-sectional structure of a conventional solid-state imaging device;

FIG. 2 is a diagram showing a cross-sectional structure of a conventional solid-state imaging device;

FIG. 3 is a diagram showing a cross-sectional structure of a conventional solid-state imaging device;

FIG. 4 is a diagram showing a cross-sectional structure of a solid-state imaging device according to a first embodiment of the present invention;

FIG. 5 is a diagram schematically showing a structure of an antireflection layer of the solid-state imaging device according to the first embodiment of the present invention;

FIG. 6 is a diagram showing the transmittance of the antireflection layer with respect to the film thickness of a first antireflection layer of the solid-state imaging device according to the first embodiment of the present invention;

FIG. 7 is a diagram showing the transmittance of the antireflection layer with respect to the film thickness of a second antireflection layer of the solid-state imaging device according to the first embodiment of the present invention;

FIG. 8 is a diagram showing a cross-sectional structure of a modification of the solid-state imaging device according to the first embodiment of the present invention;

FIG. 9 is a diagram showing a cross-sectional structure of a solid-state imaging device according to a second embodiment of the present invention;

FIG. 10 is a diagram schematically showing a structure of an antireflection layer of the solid-state imaging device according to the second embodiment of the present invention; and

FIG. 11 is a diagram showing the transmittance of the antireflection layer with respect to the film thickness of the antireflection layer of the solid-state imaging device according to the second embodiment of the present invention.

### DESCRIPTION OF THE PREFERRED EMBODIMENTS

Embodiments of a solid-state imaging device according to the present invention will be described in detail below with reference to the drawings.

### First Embodiment

A solid-state imaging device according to a first embodiment of the present invention includes antireflection layers each having a multilayer structure and preventing reflection of incident light, as Cu diffusion preventing layers, Cu making up of Cu wirings. With this, reflection of incident light is prevented, making it possible to prevent a reduction in the amount of light incident on a photodiode.

First, a configuration of the solid-state imaging device according to the first embodiment of the present invention will be described.

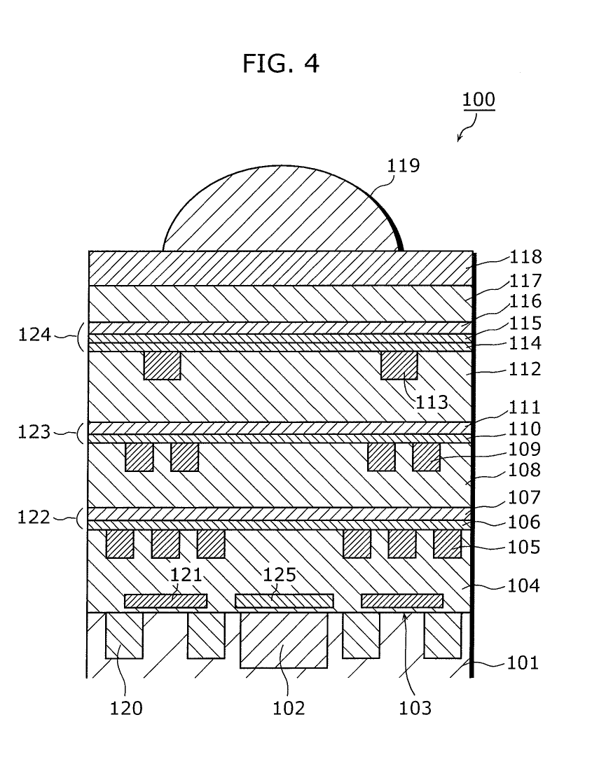

FIG. 4 is a diagram schematically showing a cross-sectional structure of the solid-state imaging device according to the first embodiment of the present invention.

A solid-state imaging device 100 shown in FIG. 4 photoelectrically converts incident light and outputs an electrical signal. The solid-state imaging device 100 is a CMOS image sensor, for example. The solid-state imaging device 100 includes a semiconductor substrate 101, a photodiode 102, a transistor 103, interlayer films 104, 108, and 112, Cu wirings 105, 109, and 113, antireflection layers 122, 123, and 124, a protective film 117, a color filter 118, a microlens 119, element isolation regions 120, and an antireflection film 125.

The semiconductor substrate 101 is made of Si, for example.

The photodiode 102 is formed on the semiconductor substrate 101. The photodiode 102 is a light-receiving element that photoelectrically converts incident light.

The transistor 103 is formed on the semiconductor substrate 101. The transistor 103 includes source/drain regions (not shown) and a gate electrode 121 formed of polysilicon. The element isolation regions 120 are an element isolation layer (STI: Shallow Trench Isolation) made of an SiO₂ buried layer.

The antireflection film 125 is formed on the photodiode 102 and below the antireflection layer 122 and prevents reflection of incident light. The antireflection film 125 is made of SiN, for example. Note that the antireflection film 125 may be made of SiON, SiC, SiNC, or SiCO.

The interlayer film 104 is stacked on the semiconductor substrate 101, the photodiode 102, the transistor 103, and the antireflection film 125. Specifically, the interlayer film 104 is stacked on a surface of the semiconductor substrate 101 where the photodiode 102 and the transistor 103 are formed. The interlayer film 108 is stacked on the antireflection layer 122. The interlayer film 112 is stacked on the antireflection layer 123. The interlayer films 104, 108, and 112 are insulating layers made of SiO₂, for example. Note that the interlayer films 104, 108, and 112 may be made of SiOC or porous silicon oxide films.

The Cu wirings 105 are formed on the interlayer film 104. The Cu wirings 109 are formed on the interlayer film 108. The Cu wirings 113 are formed on the interlayer film 112. The Cu wirings 105, 109, and 113 are metal wiring layers made of copper (Cu).

The antireflection layers 122, 123, and 124 are layers that prevent diffusion of Cu making up of the Cu wirings 105, 109, and 113 during a fabrication process. The antireflection layers 122, 123, and 124 further have the function of preventing reflection of incident light.

The antireflection layer 122 is stacked on the interlayer film 104 and the Cu wirings 105. The antireflection layer 122 includes a first antireflection layer 106 and a second antireflection layer 107. The first antireflection layer 106 is stacked on the interlayer film 104 and the Cu wirings 105. The second antireflection layer 107 is stacked on the first antireflection layer 106.

The antireflection layer 123 is stacked on the interlayer film 108 and the Cu wirings 109. The antireflection layer 123 includes a first antireflection layer 110 and a second antireflection layer 111. The first antireflection layer 110 is stacked on the interlayer film 108 and the Cu wirings 109. The second antireflection layer 111 is stacked on the first antireflection layer 110.

The antireflection layer 124 is stacked on the interlayer film 112 and the Cu wirings 113. The antireflection layer 124 includes a first antireflection layer 114, a second antireflection layer 115, and a third antireflection layer 116. The first antireflection layer 114 is stacked on the interlayer film 112 and the Cu wirings 113. The second antireflection layer 115 is stacked on the first antireflection layer 114. The third antireflection layer 116 is stacked on the second antireflection layer 115.

The reason that the antireflection layer 124 is made of three layers will be described. Though not shown, in order to electrically connect bonding pads made of Al to be formed on an upper layer after forming the first antireflection layer 114, to the Cu wirings 113, portions of the first antireflection layer 114 are removed by a photolithography process and an etching process. Then, Al is deposited on regions where the portions of the first antireflection layer 114 are removed. By the photolithography process and the etching process, Al is left only in regions where bonding pads are to be formed and Al present in all other regions including a pixel unit (above the photodiode 102) is removed. With this, bonding pads made of Al are formed on the first antireflection layer 114. Then, the second antireflection layer 115 is formed. The second antireflection layer 115 is formed to cover the bonding pads made of Al and also functions as a protective layer for the bonding pads made of Al. Note that if Al is sufficiently protected by the third antireflection layer 116 which is an upper layer and the protective film 117, the second antireflection layer 115 does not need to be formed.

The first antireflection layers 106, 110, and 114 and the second antireflection layer 115 are layers for preventing diffusion of copper making up of the Cu wirings 105, 109, and 113 during a fabrication process. The first antireflection layers 106, 110, and 114 and the second antireflection layer 115 are made of SiN, for example. Note that the first antireflection layers 106, 110, and 114 and the second antireflection layer 115 may be made of SiC or SiNC. The second antireflection layers 107 and 111 and the third antireflection layer 116 are made of a material whose refractive index is different from that of a material making up of the first antireflection layers 106, 110, and 114 and the second antireflection layer 115. The second antireflection layers 107 and 111 and the third antireflection layer 116 are made of SiON, for example. Note that the second antireflection layers 107 and 111 and the third antireflection layer 116 may be made of SiONC.

The protective film 117 is stacked on the antireflection layer 124. The protective film 117 is made of SiO₂, for example.

The color filter 118 is formed on the protective film 117. The color filter 118 is a filter that allows only light with a predetermined wavelength to pass through. The color filter 118 may, for example, be a filter that allows visible light (at wavelengths of 400 to 650 nm) to pass through. The color filter 118 may be a filter that allows red light, green light, or blue light to pass through.

The microlens 119 is formed on the color filter 118. The microlens 119 collects incident light onto the photodiode 102.

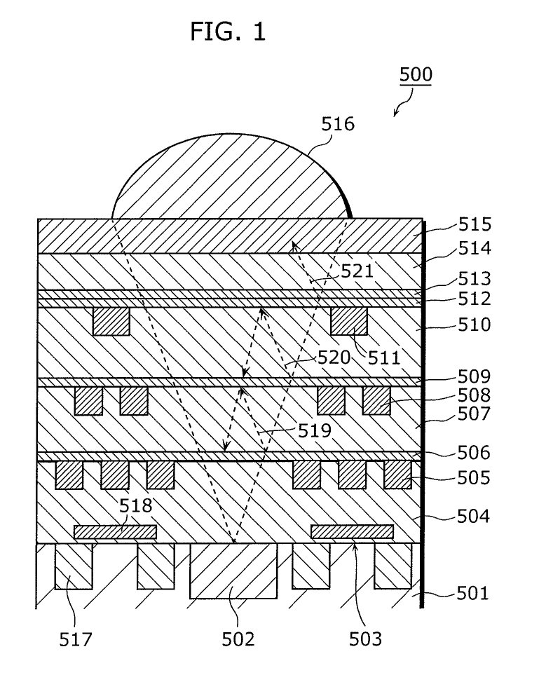

With the above-described configuration, in the solid-state imaging device 100 according to the first embodiment of the present invention, incident light is collected by the microlens 119 and the collected light sequentially passes through the color filter 118, the protective film 117, the antireflection layer 124, the interlayer film 112, the antireflection layer 123, the interlayer film 108, the antireflection layer 122, the interlayer film 104, and the antireflection film 125 and is then irradiated onto the photodiode 102. The antireflection layers 122, 123, and 124 have the function of preventing reflection of incident light (visible light). More specifically, the antireflection layers 122, 123, and 124 are optimized to achieve a high transmittance of incident light (visible light). Thus, the solid-state imaging device 100 according to the first embodiment of the present invention can reduce reflection and multiple interference occurring in the conventional solid-state imaging device 500 shown in FIG. 1. With this, the reduction in the amount of light incident on the photodiode can be prevented.

Next, a specific structure of the antireflection layers 122, 123, and 124 will be described.

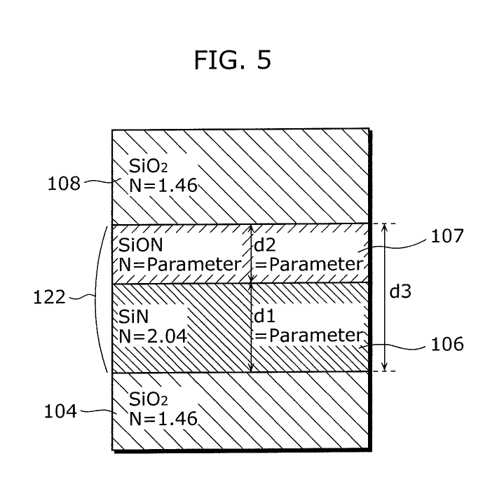

FIG. 5 is a diagram schematically showing a structure of the antireflection layer 122.

The antireflection layer 122 has a refractive index and a layer thickness that are optimized to achieve a high transmittance of incident light (visible light). Specifically, the antireflection layer 122 has a refractive index and a layer thickness which corresponds to a peak transmittance in the transmittance characteristics of incident light (visible light) with respect to the refractive index or layer thickness of the antireflection layer 122. The transmittance of the antireflection layer 122 is determined by the refractive indices of the interlayer films 104 and 108, the first antireflection layer 106, and the second antireflection layer 107, a layer thickness d1 of the first antireflection layer 106, and a layer thickness d2 of the second antireflection layer 107. Here, the refractive index N of SiO₂ making up of the interlayer films 104 and 108 is 1.46 and the refractive index N of SiN making up of the first antireflection layer 106 is 2.04. The refractive index of SiON making up of the second antireflection layer 107 can be changed by changing the composition ratio of Si/O/N. Here, the antireflection layer 122 is used to prevent diffusion of copper making up of the Cu wirings 105 during a fabrication process, and used as an etching stopper upon forming via contacts that connect the Cu wirings 105 to the Cu wirings 109. Thus, since the antireflection layer 122 functions as an etching stopper, the antireflection layer 122 needs to have a predetermined film thickness according to a process.

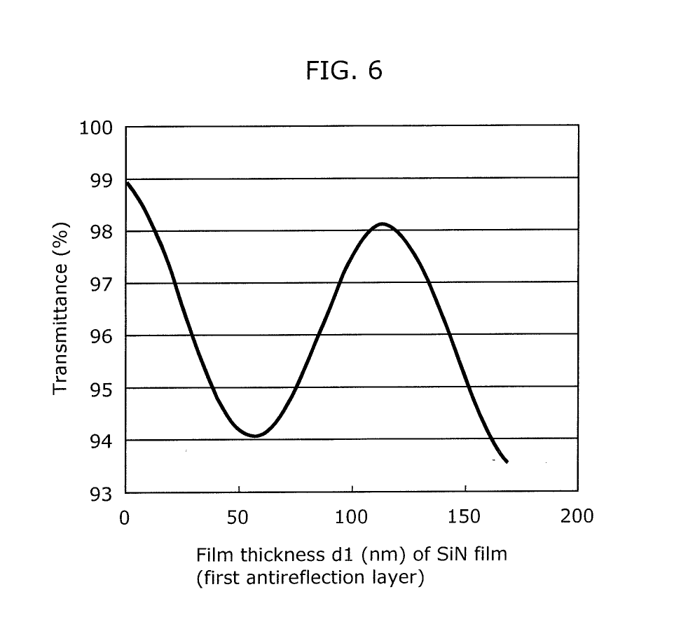

FIG. 6 is a diagram showing the transmittance of the antireflection layer 122 with respect to the film thickness d1 of the first antireflection layer 106, for the case in which a film thickness d3 of the antireflection layer 122 is 170 nm (=d1+d2). In FIG. 6, the refractive index N of SiON is 1.75 and the transmittance represented by a vertical axis shows values obtained by calculating average values of transmittances of incident light at wavelengths of 400 nm to 650 nm.

As shown in FIG. 6, there is a peak transmittance in a region where the film thickness d1 of the first antireflection layer is in the neighborhood of 110 to 120 nm. Thus, when the film thickness d3 of the antireflection layer 122 is fixed at 170 nm, by setting the film thickness d1 of the first antireflection layer to 110 to 120 nm and setting the film thickness d2(=170 nm−d1) of the second antireflection layer to 50 to 60 nm, a maximum transmittance of the antireflection layer 122 for visible light (at wavelengths of 400 nm to 650 nm) can be obtained. Note that, in FIG. 6, although the transmittance increases by approximating the film thickness d1 to zero, it is difficult to approximate the film thickness to zero and thus it is excluded.

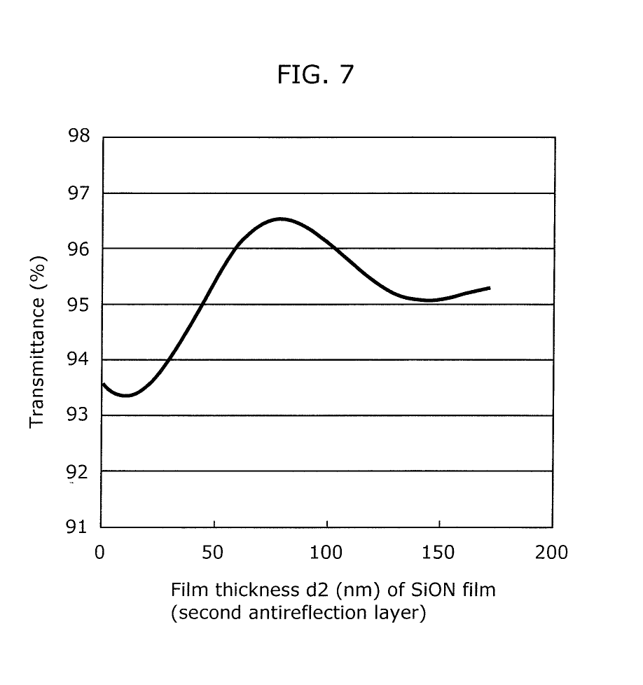

FIG. 7 is a diagram showing the transmittance of the antireflection layer 122 with respect to the film thickness d2 of the second antireflection layer 107, for the case in which the film thickness d1 of the first antireflection layer 106 is 170 nm. In FIG. 7, the refractive index N of SiON is 1.75 and the transmittance represented by a vertical axis shows values obtained by calculating average values of transmittances of incident light at wavelengths of 400 nm to 650 nm.

As shown in FIG. 7, there is a peak transmittance in a region where the film thickness d2 of the second antireflection layer is in the neighborhood of 70 to 80 nm. Thus, when the film thickness d1 of the first antireflection layer is fixed at 170 nm, by setting the film thickness d2 of the second antireflection layer to 70 to 80 nm, a maximum transmittance of the antireflection layer 122 for visible light (at wavelengths of 400 nm to 650 nm) can be obtained.

Note that as with the antireflection layer 122, maximum transmittances of the antireflection layers 123 and 124 for visible light can be obtained.

As described above, by optimizing the film thicknesses of the first antireflection layer 106 and the second antireflection layer 107 to achieve a high transmittance, reflection of incident light can be prevented. Here, the optimization represents selecting film thicknesses (layer thicknesses) of the first antireflection layer 106 and the second antireflection layer 107 in a region having a peak transmittance within an implementable range in the characteristics of transmittance of incident light (visible light) with respect to the layer thickness of the first antireflection layer 106 or the second antireflection layer 107.

Note that although for simplicity of description, in FIGS. 6 and 7, the refractive index N of SiON making up of the second antireflection layer 107 is 1.75, the film thicknesses of the first antireflection layer 106 and the second antireflection layer 107 may be set to a fixed value and the composition ratio of Si/O/N for SiON may be changed to optimize the refractive index of SiON, whereby the refractive index of the antireflection layer 122 may be optimized. Specifically, a refractive index of the second antireflection layer 107 in a region having a peak transmittance within an implementable range in the characteristics of transmittance of incident light (visible light) with respect to the refractive index of the second antireflection layer 107 may be selected. By optimizing the film thickness d1 of the first antireflection layer 106, the film thickness d2 of the second antireflection layer 107, and the refractive index of the second antireflection layer 107, the transmittance can be further improved.

As described above, by optimizing the refractive indices of the first antireflection layer 106 and the second antireflection layer 107 with respect to the refractive indices of the interlayer films 104 and 108, and the layer thickness d1 of the first antireflection layer 106 and the layer thickness d2 of the second antireflection layer 107, the antireflection layers 122, 123, and 124 each can have a refractive index and a layer thickness at which a maximum transmittance of incident light is achieved.

Next, a method of fabricating the solid-state imaging device 100 according to the first embodiment of the present invention will be described.

First, an interlayer film 104 is formed on a semiconductor substrate 101 having formed on a photodiode 102, a transistor 103, and an antireflection film 125. Portions of the interlayer film 104 are removed by a photolithography process to form trenches where Cu wirings 105 are to be buried. Then, a barrier film (not shown in FIG. 4) made of tantalum or the like and covering the bottoms and sides of the trenches is formed. After a copper seed is deposited by sputtering on the barrier film inside the trenches, Cu wirings 105 are formed by electric field plating. Then, portions of the copper and barrier film formed in areas other than the trenches are removed by polishing or the like. Subsequently, a first antireflection layer 106 is formed and then a second antireflection layer 107 is formed and then an interlayer film 108 is formed. As with the above-described fabrication process of the Cu wirings 105, trenches are formed in the interlayer film 108 and copper is deposited and then electric field plating is performed, thereby Cu wirings 109 are formed. A first antireflection layer 110 is formed and then a second antireflection layer 111 is formed and then an interlayer film 112 is formed. As with the above-described fabrication process of the Cu wirings 105 and 109, trenches are formed in the interlayer film 112 and copper is deposited and then electric field plating is performed, whereby Cu wirings 113 are formed. A first antireflection layer 114 is formed and then a second antireflection layer 115 is formed and then a third antireflection layer 116 is formed and then a protective film 117 is formed. A color filter 118 is formed and a microlens 119 is formed. In this manner, the solid-state imaging device 100 shown in FIG. 4 is formed.

Though not shown in FIG. 4, the above-described process includes a process step of forming contacts that connect the Cu wirings 105, 109, 113, source/drain regions (not shown) and the gate electrode 121. A fabrication method of forming via contacts that connect the Cu wirings 105 to the Cu wirings 109 will be described below. After the above-described interlayer film 108 is formed, first, contact holes for connecting the Cu wirings 105 to Cu wirings 109 are provided by a photolithography process. At this time, the antireflection layer 122 functions as an etching stopper. Portions of the interlayer film 108 are removed by the photolithography process to form trenches where Cu wirings 109 are to be buried. Then, a barrier film made of tantalum or the like and covering the bottoms and sides of the contact holes and trenches is formed. Copper is deposited on the barrier film inside the contact holes and trenches to form via contacts and Cu wirings 109. Then, portions of the copper and barrier film formed in areas other than the contact holes and trenches are removed by polishing or the like. With this process, via contacts for connecting the Cu wirings 105 to the Cu wirings 109 are formed. Via contacts that connect the Cu wirings 109 to the Cu wirings 113 and contacts that connect source/drain regions (not shown) and the gate electrode 121 of the transistor 103 to the Cu wirings 105 can also be formed by the same process. Note that instead of forming via contacts and contacts using copper, via contacts and contacts may be formed by depositing titanium or tungsten.

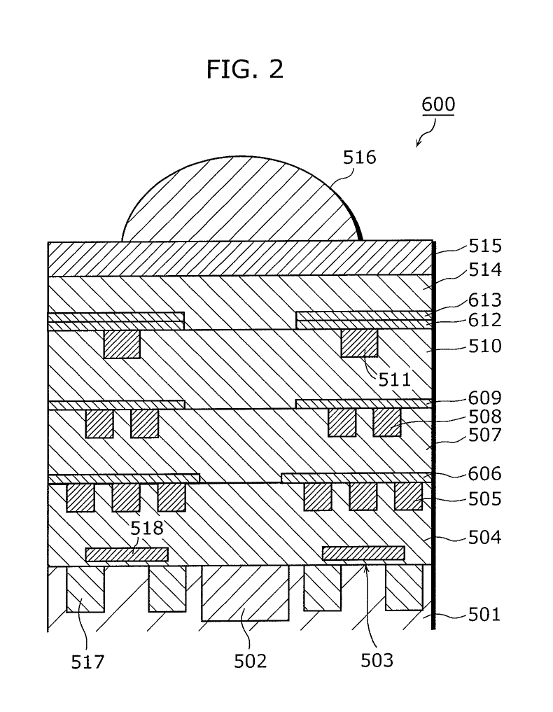

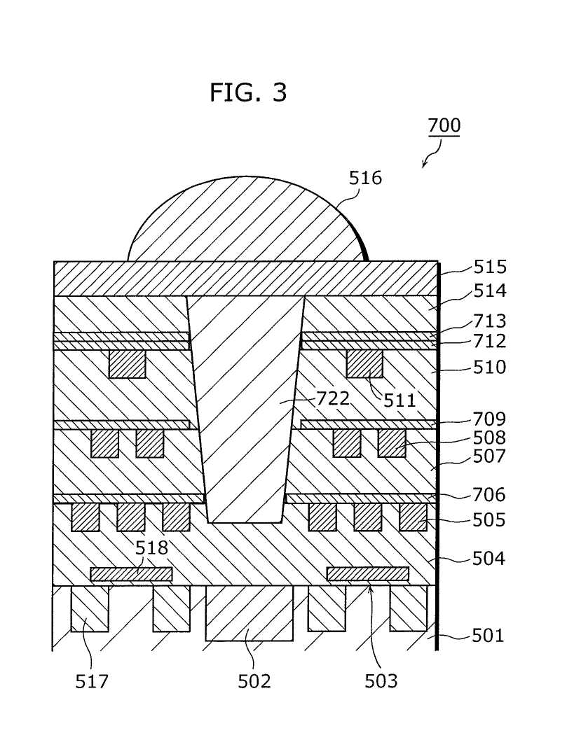

As such, comparing with the conventional solid-state imaging device 600 shown in FIG. 2, the solid-state imaging device 100 according to the first embodiment of the present invention does not require a process step of removing portions of diffusion preventing layers (antireflection layers) above a photodiode, and thus, the increase in the number of process steps can be suppressed. In addition, comparing with the conventional solid-state imaging device 700 shown in FIG. 3, there is no need to remove portions of layers above a photodiode and bury an insulating layer, and thus, the increase in the number of process steps can be suppressed. Furthermore, comparing with the conventional solid-state imaging device 700 shown in FIG. 3, a process with a high degree of difficulty of process is not used, and thus, the solid-state imaging device 100 can be formed easily.

The solid-state imaging device 100 includes the antireflection film 125 formed above the photodiode 102. With this, reflection occurring at an interface between the photodiode 102 and the interlayer film 104 can be reduced. The reflection occurring at the interface between the photodiode 102 and the interlayer film 104 has a significant influence on the reduction in the amount of light incident on the photodiode 102, over reflection occurring at interfaces between other layers (interfaces between the conventional SiN layers (diffusion preventing layers) and SiO₂ layers (interlayer films)). Thus, even when, as in the solid-state imaging device 100 according to the above-described first embodiment of the present invention, the antireflection layers 122, 123, and 124 are provided, if the antireflection film 125 is not provided on the photodiode 102, the reduction in the amount of light incident on the photodiode 102 cannot be sufficiently reduced. Meanwhile, in a solid-state imaging device having the antireflection film 125, by providing the above-described antireflection layers 122, 123, and 124, the reduction in the amount of light incident on the photodiode 102 can be more effectively reduced.

Although a solid-state imaging device according to the first embodiment of the present invention is described above, the present invention is not limited to the present embodiment.

For example, although the antireflection layers 122, 123, and 124 each are made of a layer of SiN and a layer of SiON, the antireflection layers 122, 123, and 124 each may further include a layer formed of a material whose refractive index is different from that of SiON and stacked on the layer of SiON. Alternatively, the antireflection layers 122, 123, and 124 each may be made of three or more layers whose refractive indices are different between adjacent layers. For example, the antireflection layers 122, 123, and 124 each may include a layer of SiN, a layer of SiO₂, a layer of SiN, and a layer of SiON which are stacked on top of one another. Layers included in an antireflection layer may be a combination of layers made of SiN, SiC, SiON, SiCO, SiNC, SiONC, and SiO₂. Since the antireflection layers 122, 123, and 124 need to have the effect of preventing diffusion of Cu making up of Cu wirings, it is preferable that the lowermost layer of each of the antireflection layers 122, 123, and 124 adjacent to Cu wirings be made of a material that does not contain oxygen (e.g., SiN, SiC, or SiNC). When the antireflection layers 122, 123, and 124 each are made of multiple layers, by using a material containing oxygen (e.g., SiON, SiCO, SiONC, or SiO₂) for at least one layer other than the lowermost layer, the oxygen content is changed, whereby the refractive index of that layer can be easily changed. With this, the transmittance of an antireflection layer for incident light can be easily optimized. When the antireflection layers 122, 123, and 124 each are made of three or more layers, by changing the oxygen content in a layer made of a material containing oxygen, by a multiple reflection effect, an antireflection effect on incident light can be obtained. Although in the above description the antireflection layers 122, 123, and 124 each are made of a layer made of SiN and a layer made of SiON, the antireflection layers 122, 123, and 124 may have different configurations (different materials or different numbers of layers). For example, the antireflection layer 122 may include a layer made of SiN and a layer made of SiON which are stacked on top of each other and the antireflection layer 123 may include a layer made of SiN, a layer made of SiO₂, a layer made of SiN, and a layer made of SiON which are stacked on top of one another.

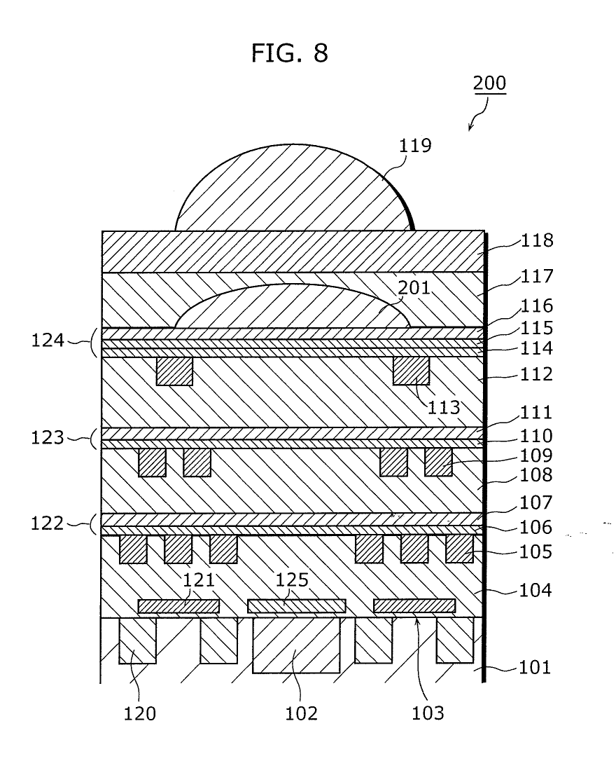

Although the cross-sectional structure shown in FIG. 4 is provided as the configuration of the solid-state imaging device according to the above-described embodiment, the configuration may further include an inner lens. FIG. 8 shows a modification of the solid-state imaging device 100 according to the first embodiment and is a diagram schematically showing a cross-sectional configuration of a solid-state imaging device having an inner lens. In a solid-state imaging device 200 shown in FIG. 8, an inner lens 201 is further provided to the configuration of the solid-state imaging device 100 shown in FIG. 4. The inner lens 201 is formed on an antireflection layer 124 and made of SiN, for example.

### Second Embodiment

A solid-state imaging device according to a second embodiment of the present invention includes antireflection layers each having a single-layer structure and preventing reflection of incident light, as Cu diffusion preventing layers, Cu making up of Cu wirings. With this, reflection of incident light is prevented, making it possible to reduce a reduction in the amount of light incident on a photodiode.

First, a configuration of the solid-state imaging device according to the second embodiment of the present invention will be described.

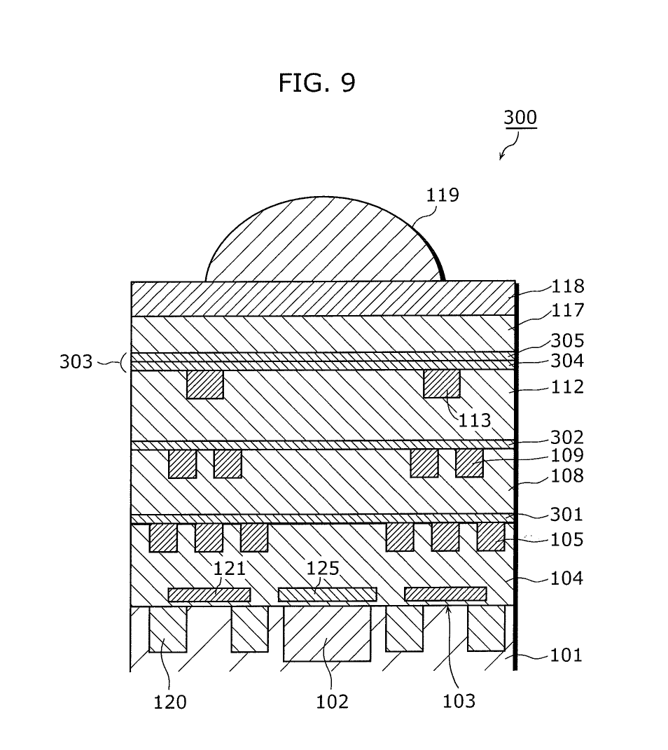

FIG. 9 is a diagram schematically showing a cross-sectional structure of the solid-state imaging device according to the second embodiment of the present invention. Note that the same components as those described in FIG. 4 are denoted by the same reference numerals and a detailed description thereof will be omitted.

A solid-state imaging device 300 shown in FIG. 9 is different from the solid-state imaging device 100 according to the first embodiment shown in FIG. 4 in that antireflection layers 301, 302, and 303 each made of a single layer (a layer formed of a single material) are provided instead of the antireflection layers 122, 123, and 124.

The antireflection layers 301, 302, and 303 are layers for preventing diffusion of copper making up of Cu wirings 105, 109, and 113 during a fabrication process. Furthermore, the antireflection layers 301, 302, and 303 are layers that prevent reflection of incident light. The antireflection layer 303 includes a first antireflection layer 304 and a second antireflection layer 305 stacked on the first antireflection layer 304. The antireflection layers 301 and 302, the first antireflection layer 304, and the second antireflection layer 305 are made of SiN, for example. Note that the antireflection layers 301 and 302, the first antireflection layer 304, and the second antireflection layer 305 may be made of SiC or SiNC.

With the above-described configuration, in the solid-state imaging device 300 according to the second embodiment of the present invention, incident light is collected by a microlens 119 and the collected light sequentially passes through a color filter 118, a protective film 117, the antireflection layer 303, an interlayer film 112, the antireflection layer 302, an interlayer film 108, the antireflection layer 301, an interlayer film 104, and a antireflection film 125 and is then irradiated onto a photodiode 102. The antireflection layers 301, 302, and 303 are optimized to achieve a high transmittance of incident light (visible light). Thus, the solid-state imaging device 300 according to the second embodiment of the present invention can reduce reflection and multiple interference occurring in the conventional solid-state imaging device 500 shown in FIG. 1. With this, the reduction in the amount of light incident on the photodiode can be prevented.

Next, a specific structure of the antireflection layers 301, 302, and 303 will be described.

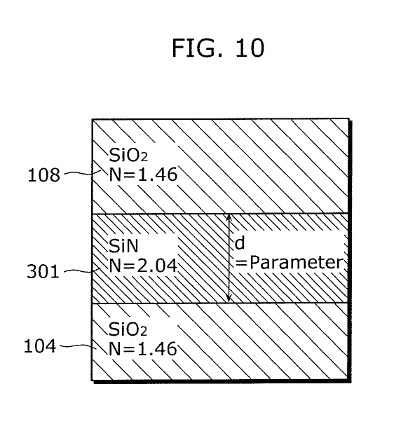

FIG. 10 is a diagram schematically showing a structure of the antireflection layer 301.

The antireflection layer 301 has a refractive index and a layer thickness that are optimized to achieve a high transmittance of incident light (visible light). Specifically, the antireflection layer 301 has a refractive index and a layer thickness which corresponds to a peak transmittance in the transmittance characteristics of incident light (visible light) with respect to the layer thickness of the antireflection layer 301. The transmittance of the antireflection layer 301 is determined by the refractive indices of the interlayer films 104 and 108 and the antireflection layer 301 and a layer thickness d of the antireflection layer 301. Here, the refractive index N of SiO₂ making up of the interlayer films 104 and 108 is 1.46 and the refractive index N of SiN making up of the antireflection layer 301 is 2.04.

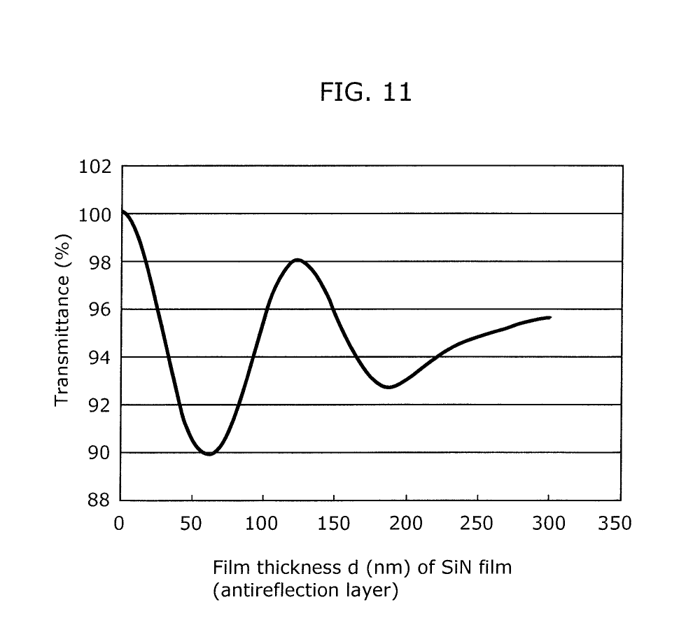

FIG. 11 is a diagram showing the transmittance of the antireflection layer 301 with respect to the film thickness d of the antireflection layer 301. In FIG. 11, the transmittance represented by a vertical axis shows values obtained by calculating average values of transmittances of incident light at wavelengths of 400 nm to 650 nm.

As shown in FIG. 11, there is a peak transmittance in a region where the film thickness d of the antireflection layer 301 is in the neighborhood of 120 to 130 nm. Thus, by setting the film thickness d of the antireflection layer 301 to 120 to 130 nm, a maximum transmittance of the antireflection layer 301 for visible light (at wavelengths of 400 nm to 650 nm) can be obtained. Note that as with the antireflection layer 301, maximum transmittances of the antireflection layers 302 and 303 for visible light can be obtained. As described above, by optimizing the film thickness d of a antireflection layer to achieve a high transmittance, reflection of incident light can be prevented. Specifically, by selecting a film thickness d of the antireflection layer 301 in a region having a peak transmittance within an implementable range in the characteristics of transmittance of incident light (visible light) with respect to the film thickness d of the antireflection layer 301, reflection of incident light can be prevented.

A fabricating method of the solid-state imaging device 300 according to the second embodiment of the present invention is the same as the method of fabricating the solid-state imaging device 100 according to the above-described first embodiment except that a process step of forming the second antireflection layers 107 and 111 and the third antireflection layer 116 which are made of SiON is not performed, and thus, the description thereof will be omitted.

As such, comparing with the conventional solid-state imaging device 600 shown in FIG. 2, the solid-state imaging device 300 according to the second embodiment of the present invention does not require a process step of removing portions of diffusion preventing layers (antireflection layers) above a photodiode, and thus, the increase in the number of process steps can be suppressed. In addition, comparing with the conventional solid-state imaging device 700 shown in FIG. 3, there is no need to remove portions of layers above a photodiode and embed an insulating layer, and thus, the increase in the number of process steps can be suppressed. Furthermore, comparing with the conventional solid-state imaging device 700 shown in FIG. 3, a process with a high degree of difficulty of process is not used, and thus, the solid-state imaging device 300 can be formed easily.

The solid-state imaging device 300 includes the antireflection film 125 formed on the photodiode 102. With this, reflection occurring at an interface between the photodiode 102 and the interlayer film 104 can be reduced. The reflection occurring at the interface between the photodiode 102 and the interlayer film 104 has a significant influence on the reduction in the amount of light incident on the photodiode 102, over reflection occurring at interfaces between other layers (interfaces between the conventional SiN layers (diffusion preventing layers) and SiO₂ layers (interlayer films)). Thus, even when, as in the solid-state imaging device 300 according to the second embodiment of the present invention, the antireflection layers 301, 302, and 303 are provided, if the antireflection film 125 is not provided on the photodiode 102, the reduction in the amount of light incident on the photodiode 102 cannot be sufficiently reduced. Meanwhile, in a solid-state imaging device having the antireflection film 125, by providing the above-described antireflection layers 301, 302, and 303, the reduction in the amount of light incident on the photodiode 102 can be more effectively reduced.

Comparing the solid-state imaging device 300 according to the second embodiment of the present invention with the solid-state imaging device 100 according to the first embodiment, since in the solid-state imaging device 300 according to the second embodiment the antireflection layers 301, 302, and 303 each are made of a single layer (a layer made of the same material), the number of fabrication process steps can be further reduced. On the other hand, in the solid-state imaging device 100 according to the first embodiment, by forming each of the antireflection layers 122, 123, and 124 in a multilayer structure, the number of parameters that determine the transmittance of the antireflection layer increases, and thus, flexibility upon determining the transmittance increases. Furthermore, an antireflection layer with high transmittance can be easily implemented.

Although a solid-state imaging device according to the second embodiment of the present invention is described above, the present invention is not limited to the present embodiment.

For example, as with the modification of the solid-state imaging device according to the first embodiment shown in FIG. 8, an inner lens may be further provided to the structure shown in FIG. 9.

Although the case is described in which solid-state imaging devices according to the first and second embodiments use three layers of metal (copper) wirings, metal wirings may have a structure with one, two, four or more layers.

Although the case is described in which in solid-state imaging devices according to the first and second embodiments a diffusion preventing layer having an antireflection function is formed for each of three layers of metal (copper) wirings, by forming at least one of the three diffusion preventing layers to be the above-described antireflection layer, the reduction in the amount of light incident on the photodiode 102 can be suppressed.

Although the case is described in which in the first and second embodiments copper (Cu) wirings are used as metal wirings, the structure of the present invention can be applied even when metal wirings formed of a material which a diffusion prevention layer having a different refractive index from that of interlayer films needs to be formed to prevent deterioration in characteristics due to diffusion or the like in a fabrication process.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to a solid-state imaging device. More particularly, the present invention can be applied to a CMOS image sensor for use in a digital camera, a mobile phone camera, a web camera, etc.

What is claimed is:

1. A solid-state imaging device comprising:
a semiconductor substrate;
a light-receiving element formed on said semiconductor substrate and which photoelectrically converts incident light; and
a plurality of wiring layers stacked on top of each other on a surface of said semiconductor substrate where said light-receiving element is formed,
wherein at least one of said plurality of wiring layers includes:
a first insulating layer;
a metal wiring formed on said first insulating layer;
an antireflection layer stacked on said first insulating layer and said metal wiring, and which prevents diffusion of a material making up of said metal wiring and prevents reflection of the incident light; and
a second insulating layer stacked on said antireflection layer.

2. The solid-state imaging device according to claim 1,
wherein said antireflection layer has a refractive index or layer thickness which corresponds to a peak transmittance in transmittance characteristics of the incident light with respect to the refractive index or layer thickness of said antireflection layer.

3. The solid-state imaging device according to claim 1,
wherein said antireflection layer includes:
a first antireflection layer stacked on said first insulating layer and said metal wiring; and
a second antireflection layer stacked on said first antireflection layer and made of a material having a refractive index different from a refractive index of a material making up of said first antireflection layer.

4. The solid-state imaging device according to claim 3,
wherein said first antireflection layer is made of a material that does not contain oxygen.

5. The solid-state imaging device according to claim 4,
wherein the material that does not contain oxygen is SiN, SiC, or SiNC.

6. The solid-state imaging device according to claim 3,
wherein said second antireflection layer is made of a material that contains oxygen.

7. The solid-state imaging device according to claim 6,
wherein the material that contains oxygen is SiON, SiONC, or SiO₂.

8. The solid-state imaging device according to claim 3,
wherein said antireflection layer further includes
a third antireflection layer stacked on said second antireflection layer and made of a material having a refractive index different from that of the material making up of said second antireflection layer.

9. The solid-state imaging device according to claim 1, further comprising
an antireflection film which is formed on said light-receiving element and below said plurality of wiring layers and prevents reflection of the incident light.

10. The solid-state imaging device according to claim 1,
wherein said metal wiring is made of copper.
